(19) United States
(12) Patent Application Publication
(10) Pub. No.: US 2013/0078901 A1
(43) Pub. Date: Mar. 28, 2013

(54) COOLING SYSTEMS AND METHODS FOR DATA CENTERS

(71) Applicants: Daniel J. CURTIN, Alexandria, VA (US); William W. REYNOLDS, Pasadena, MD (US); Daniel B. KENNEDY, Lovettsville, VA (US); Peter STRAPP, Silver Spring, MD (US)

(72) Inventors: Daniel J. CURTIN, Alexandria, VA (US); William W. REYNOLDS, Pasadena, MD (US); Daniel B. KENNEDY, Lovettsville, VA (US); Peter STRAPP, Silver Spring, MD (US)

(73) Assignee: KINGSPAN HOLDINGS (IRL) LIMITED, Co Cavan (IE)

(21) Appl. No.: 13/242,773

(22) Filed: Sep. 23, 2011

(51) Int. Cl. H05K 5/02

(52) U.S. Cl. 454/184

(57) ABSTRACT

A cooling system for selectively cooling the hot aisles of a data center is disclosed. The cooling system includes a source of cooling air, a relief damper configured to selectively allow cooling air from the source of cooling air to enter directly into the hot aisle, and a mechanism to move the relief damper between open and closed positions.

### BACKGROUND

1. Field of the Invention

This invention relates to data center cooling systems and methods. In particular, this invention relates to systems and methods for cooling data centers having hot aisles.

2. Background of the Invention

A typical data center includes spaced rows of IT racks that contain and/or support a variety of IT hardware/equipment. The IT hardware/equipment contained in and supported by those racks, and the associated peripheral equipment and cables, generate a relatively high amount of heat. Because of that heat, providing adequate cooling to the IT racks in the data center is of paramount importance. Moreover, it is desirable that the IT racks be cooled as efficiently as possible, as the energy costs to cool the IT racks may approach a large percentage of the energy costs to operate the data center.

As stated, the IT racks in a data center are usually in spaced rows, such that aisles are formed between adjacent rows. A recognized method to increase cooling system efficiency in data centers is to have some of those aisles be dedicated cold aisles and some of those aisles be dedicated hot aisles. A cold aisle is an aisle that receives cooling air from a source of cooling air and provides it to an IT rack or multiple IT racks. A hot aisle is an aisle that receives the air after it passes through an IT rack or multiple IT racks and serves as a conduit or passageway for that air to enter an data center air exit conduit or as the exit conduit itself. Thus, the path of cooling air is from the source of cooling air, through the cold aisles, through one or more IT racks, through the hot aisles, and directly out of the data center or to a data center air exit conduit.

In a cold/hot aisle arrangement, the air paths through the cold aisles and hot aisles are wholly or partially segregated, to ensure the elimination of or to minimize commingling of the air in the two types of aisles. This prevents the air in the hot aisles from increasing the temperature of the air in the cold aisles before the air in the cold aisles passes through the IT racks.

Data centers typically have a raised floor system, often called an access floor system. An access floor system is usually comprised of a continuous array of floor panels, arranged edge-to-edge, and supported above the sub-floor by support structure. The array of access floor panels usually extends wall-to-wall in the data centers. The IT racks are placed on top of and supported by the array of floor panels.

A plenum is formed between the sub-floor and the access floor panel array. The cables and other equipment run through the plenum, and the plenum is also used as a conduit for cooling air. Often, one or more air conditioning units supply air to the plenum, and some of the access floor panels in the array have grates and/or other openings. The cooling air passes through the grates and other openings into the data center.

In a typical data center having an access floor system and hot and cold aisles, the cooling air passes through the grates or other openings into the cold aisles. The cooling air then enters the faces of the IT racks that partially form the cold aisles, and passes through the IT racks, cooling the hardware/equipment contained in and/or supported by the IT racks. The cooling air next exits the IT racks, as heated air, and enters into one of the hot aisles. The heated air in the hot aisles is then cycled back to one or more air conditioning units through a return duct.

One way to increase the efficiency of a data center cooling system is to increase the temperature of the cooling air provided to the cold aisles. However, this increase in the cold aisle temperature results in increased temperatures in the hot aisles during normal operation, because the delta temperature value, which is the rise in temperature as the air passes through the IT racks, remains substantially the same for the same IT rack. That is, the delta temperature value will be substantially the same, regardless of the starting temperature of the cooling air in the cold aisles.

The increase in cooling air temperatures, coupled with a gradual increase in IT equipment/hardware delta temperature values, further results in even higher hot aisle temperatures. For example, delta temperature values in present IT equipment/hardware can range from 25-60° F., while supply temperatures based on ASHRAE (American Society of Heating, Refrigerating and Air-Conditioning Engineers) recommendations can be as high as 80.6° F., resulting in possible hot aisle temperatures in up to about of 140° F.

The elevated hot aisle temperatures are acceptable when the hot aisles are not occupied (e.g., when a technician is not working in the hot aisles). However, the elevated hot aisle temperatures can greatly affect the amount of time a technician can be expected/allowed to work in the hot aisles. For example, the maximum working conditions with a 25% work cycle/75% rest cycle is approximately 117° F. Continuous work requirements require further reduction of the temperature in the hot aisle.

### SUMMARY

In view of the above, it is desirable and energy efficient to reduce the temperature in a hot aisle of a data center when a person is going to be in the hot aisle, but to allow the temperature in the hot aisle to be higher when no one is in the hot aisle.

The data center cooling system of this invention is for a data center having at least one hot aisle and at least one cold aisle. The system includes a relief damper that is configured to selectively allow cooling air from the source of cooling air to enter directly into the hot aisle. The system includes a mechanism that controls the position of the relief damper between open and closed positions. The relief damper, when open, permits air to pass from the plenum to the hot aisle and, when closed, prevents air from passing from the plenum into the hot aisle. There can be multiple open positions, if desired.

In some embodiments of the invention, the source of cooling air is a plenum formed between the array of panels of a raised access floor system and the subfloor.

According to other embodiments, the relief damper may be operated by a manual switch that switches the relief damper from the closed position to an open position, and vice versa.

The cooling systems of this invention may include an indicator that signals that the relief damper is in an open position. The indicator may provide a visual signal and/or an audio signal. The indicator may be powered by an airflow through the relief damper when it is in an open position.

According to other embodiments, the data center cooling system may have a hot aisle occupation sensor unit that senses when a person is in the hot aisle. The data center cooling system may have a control unit that controls the relief damper based on the output of the hot aisle occupation sensor unit. The hot aisle occupation sensor unit may comprise a motion or pressure sensor to detect the presence of a person in the hot aisle.

In other embodiments, the control unit may control the relief damper based on the temperature sensed by a temperature sensor in the hot aisle.

According to other embodiments, an actuator may be provided outside the hot aisle that, upon being actuated, signals or instructs the cooling system to reduce the temperature in the hot aisle by opening the relief damper.

In certain embodiments, a display unit may also be positioned outside the hot aisle. The display unit may indicate the temperature in the hot aisle. The display unit may also display whether it is permissible to enter the hot aisle, for example, by displaying a red light, indicating that a temperature in the hot aisle is too high, or a green light, indicating that a temperature in the hot aisle is acceptable.

Another aspect of this invention is a method for selectively and directly cooling a hot aisle of a data center. The method may comprise selectively opening a relief damper located between a source of cooling air and the hot aisle to directly provide cooling air from the source of cooling air to the hot aisle.

According to another embodiment, the method for selectively and directly cooling a hot aisle of a data center may further comprise sensing whether a person is in the hot aisle, and controlling the relief damper based on the output of the sensor.

### BRIEF DESCRIPTION OF THE DRAWINGS

Various exemplary embodiments of this invention will be described in detail with reference to the drawings in which:

FIG. 1 is a schematic view of a data center cooling system according to one embodiment.

FIG. 2 is a schematic view of a data center cooling system according to another embodiment.

FIG. 3 is a block diagram illustrating selected components of the data center cooling system according to the embodiment of FIG. 2.

### DETAILED DESCRIPTION OF EMBODIMENTS

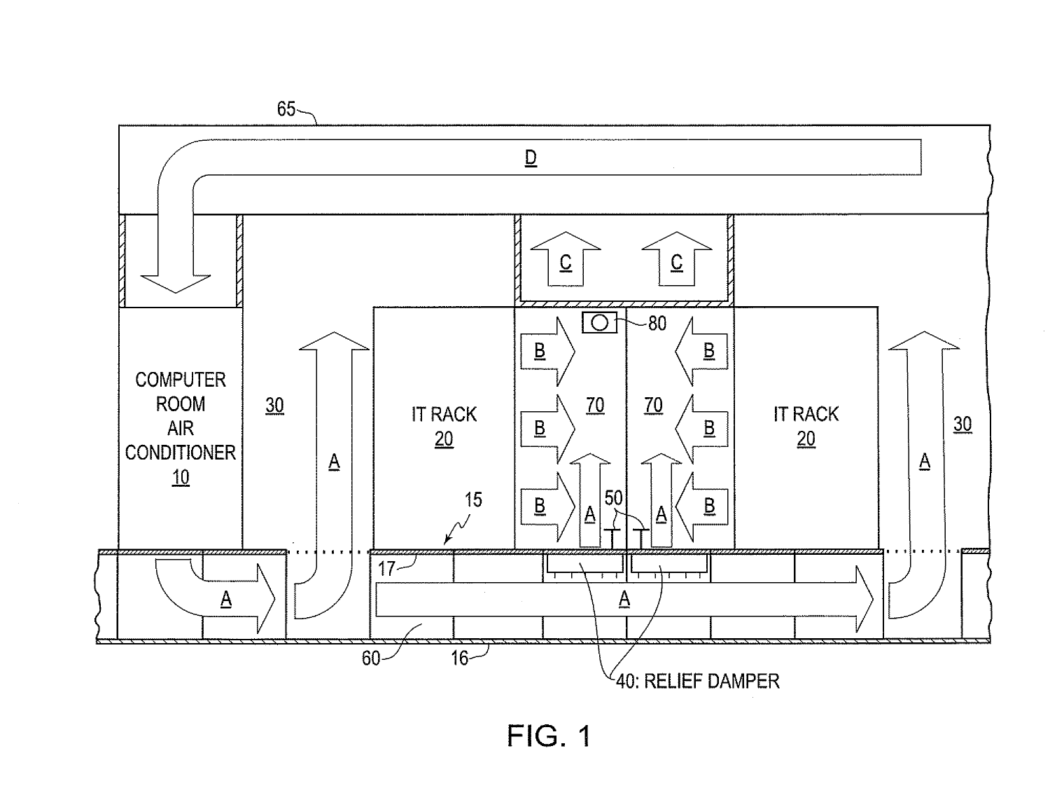

As illustrated in FIG. 1, a data center typically includes one or more air conditioning units 10, an access floor system 15 that consists of an array of access floor panels 17 supported above the subfloor 16 and positioned edge-to-edge to form a continuous raised floor surface above subfloor 16, one or more IT racks 20, and a return air plenum 65.

The IT racks 20 are supported by the access floor panels 17 and are usually positioned in spaced rows. The IT racks 20 contain and/or support IT hardware and other data center electronic equipment.

Hot aisles 70 and cold aisles 30 are formed on opposite sides of the rows of IT racks 20. Air in the hot aisles 70 and the cold aisles 30 is precluded, partially or wholly, from commingling.

While FIG. 1 illustrates a data center having only two IT racks 20, two cold aisles 30 and one hot aisle 70, it should be understood that data centers in which the cooling system of this invention can be utilized can include any number of IT racks 20 (arranged in any number of rows), cold aisles 30 and hot aisles 70.

The air conditioning unit 10 provides cooling air A to plenum 60 formed between the array of access floor panels 17 and the subfloor 16. The cooling air A passes through grates or other openings in the array of access floor panels 17 into cold aisles 30.

The cooling air then passes from cold aisles 30 into the sides of the IT racks 20 that partially form the cold aisles 30 and through those racks, thereby cooling the IT equipment/hardware contained in and/or supported by the IT racks 20. The cooling air is next exhausted from the opposite sides of the IT racks 20, as heated exhaust air B, into the hot aisle 70. An airflow C exits the hot aisle 70 and enters the return plenum 65, forming a return airflow D that is cycled back to the air conditioning unit 10.

The cooling air A that is provided to the cold aisles 30 can be, for example, 80° F. or more. As discussed above, having a cooling air temperature of 80° F. or more may result in temperatures in the hot aisles 70 in excess of 140° F., which is undesirably high during periods in which a technician needs to be in the hot aisle 70 to perform maintenance or other work on the IT equipment/hardware that is contained in and/or supported by the IT racks 20.

In the FIG. 1 embodiment of this invention, one or more relief dampers 40 are provided in or adjacent to openings in the array of access floor panels 17 to selectively allow the cooling air A to pass directly to the hot aisle 70. FIG. 1 illustrates two relief dampers 40, but the number of relief dampers 40 is not limited to two, and any number of relief dampers 40 can be employed.

The relief dampers 40 have at least one open position and a closed position. The cooling air A is allowed to pass directly from the plenum 60 to the hot aisle 20 when the relief dampers 40 are in the open position(s). Conversely, when the relief dampers 40 are in the closed position, they prevent the cooling air A from passing directly into the hot aisle 70. The relief dampers 40 may have various open positions, such that the quality of air that passes through them varies, depending on the selected open position.

When the relief dampers 40 are in an open position, the entry of cooling air A directly into the hot aisle 70 reduces the temperature in the hot aisle 70, at least temporarily. Technicians can enter the hot aisle 70 during periods when the temperature in the hot aisle 70 is reduced to maintain, service or do other work on the IT equipment/hardware contained in and/or supported by IT racks 20.

In the embodiment illustrated in FIG. 1, the relief dampers 40 are moved from their closed position to an open position, and vice versa from an open position to their closed position, by means of a manually operated switch 50, which can be provided inside or outside the hot aisle 70. The manually operated switch 50 can be, for example, a lever or other mechanism that is operated by hand, or a mechanism that is operated by a tool.

An indicator 80 may be provided that indicates when the relief dampers 40 are in open and/or closed positions. The indicator 80 may be a visual indicator or an audio indicator. One function of the indicator 80 is to remind a technician working in the hot aisle 70 that the relief dampers 40 are still in an open position when the technician is done working in the hot aisle 70, so that the technician changes the position of the relief dampers 40 from an open position to the closed position at the conclusion of his/her work session. If the indicator is a visible indicator, it may be a blinking red light, or any other type of visible indicator. If the indicator is an audio indicator, it may provide a beeping or buzzing noise that is loud enough to be heard over the noise generated by the IT hardware/equipment contained in and/or supported by IT racks 20. In the case where the visual and/or audio indicators require power to operate, the power can be provided via a turbine that generates power via the cooling air A passing through the relief dampers 40. Alternatively, the indicator can also be electrically powered, such as by a battery or a direct electrical connection to an outlet.

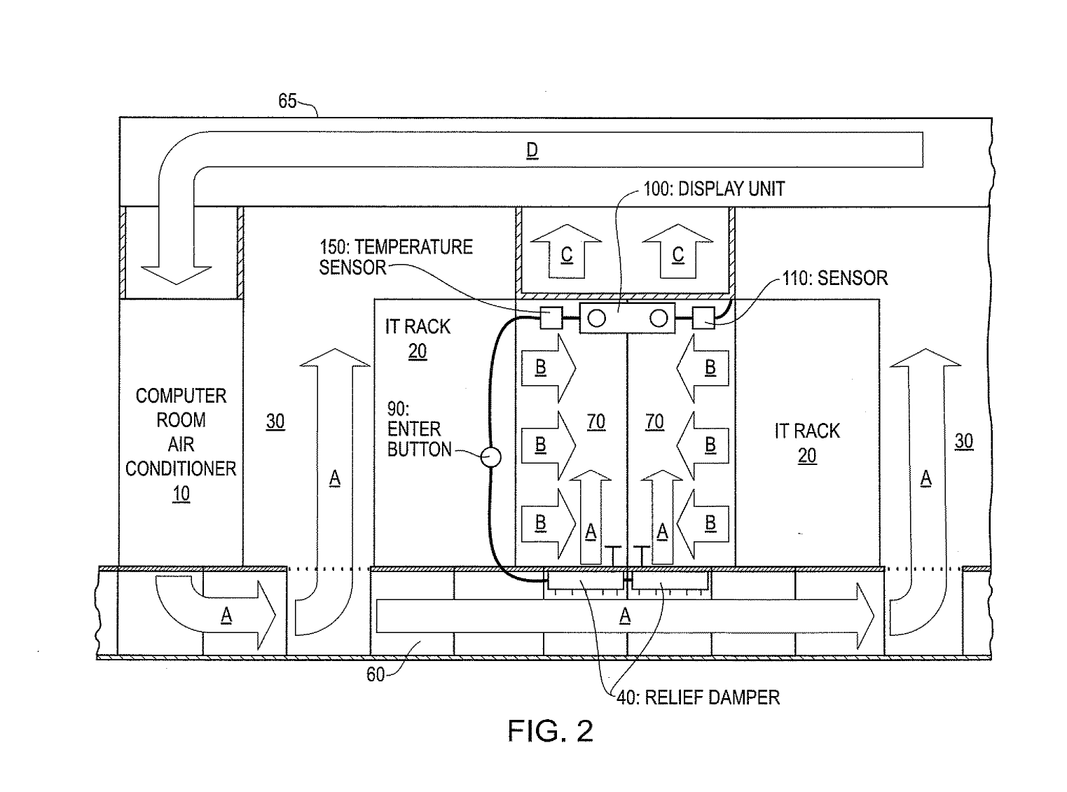

FIG. 2 illustrates another embodiment of this invention in which the relief dampers 40 are electronically controlled instead of being manually controlled. The system illustrated in the embodiment of FIG. 2 includes an actuator, such as an enter button 90, that is actuated when a technician wants to work in the hot aisle 70. The enter button 90 may be provided outside the hot aisle 70, either in a cold aisle 20, as shown in FIG. 2, or outside the data center.

In this embodiment, upon depressing the enter button 90, the relief dampers 40 are opened via a motor 160 to allow cooling air A to enter the hot aisle 70. The enter button 90 may also control the opening of a door or other closure into the hot aisle 70. That is, when button 90 is activated, it may cause both the relief dampers 40 to move from the closed to an open position and the door or other closure to the hot aisle 70 to open. While a button is illustrated in the figures and discussed above, any other actuator switch mechanism can be utilized.

A temperature sensor 150 may be provided to monitor the temperature in the hot aisle 70. The temperature in the hot aisle 70 may be displayed on a display unit 100. The display unit 100 may include a red light or other signal indicating that it is not acceptable to be in the hot aisle 70, and may include a green light or other signal indicating that it is acceptable to be in the hot aisle 70.

The embodiment illustrated in FIG. 2 may also include a sensor 110 that detects a person in the hot aisle 70. The sensor 110 may, for example, use infrared light or laser light to detect a person in the hot aisle 70. The sensor 110 may be a motion sensor, one or more pressure sensors provided in the floor of the hot aisle 70, or any other type sensor that would detect a person in the hot aisle 70.

Output from the sensor 110 may be utilized to exclusively determine whether the relief dampers 40 should be in the open position or closed position. That is, the system can be designed such that the relief dampers are opened and remain open when a person is detected in the hot aisle 70. The relief dampers are closed if a person is not detected for a predetermined amount of time.

The sensor 110 can also function as an auxiliary control for the relief dampers. For example, there can be another mechanism that is employed to move the relief damper to the open position, and the relief damper will remain in the open position for as long as the sensor senses a person in the hot aisle or for a certain period of time after the sensor ceases sensing a person in the hot aisle.

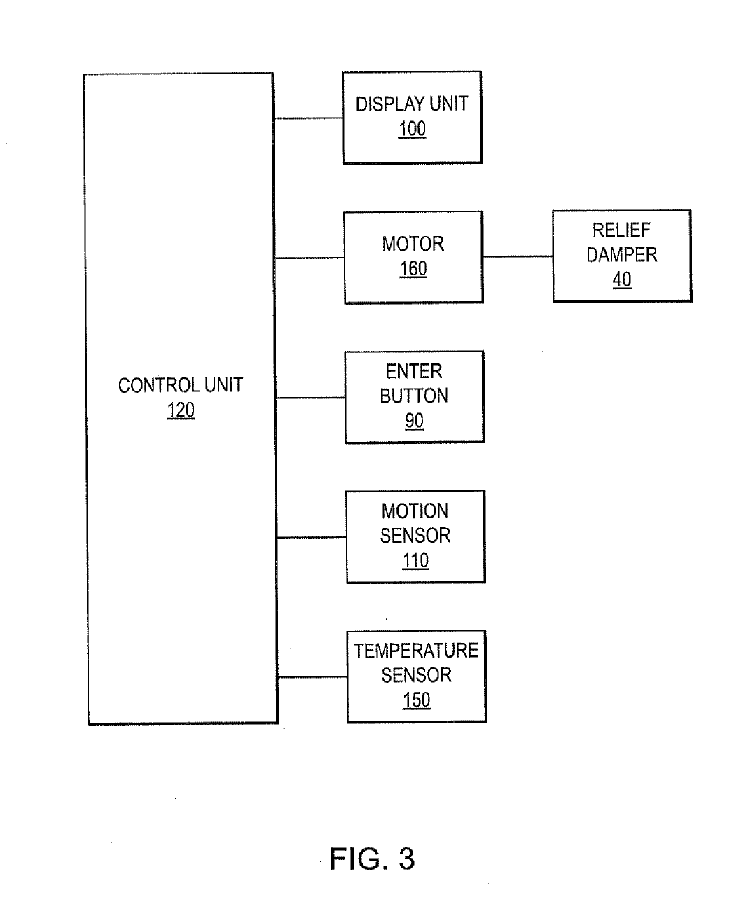

As illustrated in the block diagram of FIG. 3, a control unit 120 controls the operation of the relief dampers 40 in the embodiment illustrated in FIG. 2. The control unit 120 may receive a signal from the enter button 90 and controls the motors 160 to open or close the relief dampers 40 based on that signal. The control unit 120 may also receive a signal from sensor 110 and the control the motors 160 based on that signal, in whole or in part, as discussed above. The control unit 120 also controls the display unit 100 to display the temperature in the hot aisle 70 based on the output of the temperature sensor 150. The control unit 120 may also automatically control the degree of openness of the relief dampers 40 based on an output of the temperature sensor 150. The control unit 120 may be a central processing unit (CPU) provided in a computer having a memory such as a flash memory, ROM or hard drive.

The exemplary embodiments of the data room cooling system and method discussed above and illustrated by the figures are intended to be illustrative and not limiting. Various changes may be made without departing from the spirit and scope of the invention. For example, providing the cooling air to the cold aisles and the hot aisles via a plenum in an access floor system and through grates or other openings in the array of access floor panels is but one way of providing the cooling air to those aisles. The cooling air may be provided to those aisles through any other means and this invention is not limited particularly to data centers having a raised access floor system. Similarly, while the return air plenum is illustrated in the ceiling of the data room in the Figures, that plenum can be located anywhere so long as it forms a conduit between the hot aisles and the air-conditioning units.

What is claimed is:

1. A cooling system for a data center that includes a plurality of IT racks and at least one cold aisle and at least one hot aisle that are located on opposite sides of at least one of the plurality of IT racks, the opposite sides of the at least one of the plurality of IT racks partially defining the at least one cold aisle and the at least one hot aisle, the cooling system comprising:
a source of cooling air that supplies cooling air to the at least one cold aisle;
a relief damper configured to selectively allow the cooling air from the source of cooling air one to enter directly into the at least one hot aisle; and
a mechanism to control movement of the at least one relief damper between open and closed positions.

2. The cooling system for a data center according to claim 1, wherein
the source of cooling air includes a plenum formed below panels of an access floor system and the relief damper is positioned in an opening in the panels.

3. The cooling system for a data center according to claim 2, wherein the mechanism is a mechanical actuator.

4. The cooling system for a data center according to claim 3, further comprising an indicator that emits a signal when the relief damper is in the open position.

5. The cooling system for a data center according to claim 1, wherein the mechanism is a mechanical actuator.

6. The cooling system for a data center according to claim 1, further comprising an indicator that emits a signal when the relief damper is in the open position.

7. The cooling system for a data center according to claim 1, wherein the mechanism is an electric actuator.

8. The cooling system for a data center according to claim 7, further comprising an indicator that emits a signal when the relief damper is in the open position.

9. The cooling system for a data center according to claim 8, wherein the signal is generated by an airflow through the relief damper when the relief damper is in the open position.

10. The cooling system for a data center according to claim 7, wherein the mechanism causes both the relief damper to move from the closed position to the open position and a data center closure to open to permit access to the at least one hot aisle.

11. The cooling system for a data center according to claim 1, further comprising:
a hot aisle occupation sensor that senses whether a person is present in the at least one hot aisle;
wherein output from the hot aisle occupation sensor is used to at least partially control the position of the relief damper.

12. The cooling system for a data center according to claim 11, wherein the hot aisle occupation sensor comprises a motion sensor.

13. The cooling system for a data center according to claim 1, further comprising:
an actuator positioned outside the at least hot aisle that, upon being actuated, signals the cooling system to open the relief damper.

14. The cooling system for a data center according to claim 13, further comprising:
a display unit that is positioned outside the at least one hot aisle and that indicates the temperature in the at least one hot aisle.

15. A method for selectively, directly cooling a hot aisle of a data center comprising:
providing a source of cooling air for the data center;
selectively opening a relief damper to allow cooling air from the source of cooling air to directly enter the hot aisle; and
closing the relief damper to prevent the cooling air from the source of cooling air from directly entering into the hot aisle.

16. The method for selectively, directly cooling a hot aisle of a data center according to claim 14, wherein the source of cooling air is a plenum formed below panels of an access floor system and the relief damper is positioned in an opening in the panels.

17. The method for selectively, directly cooling a hot aisle of a data center according to claim 14, wherein the relief damper is operated by a manual actuator.

18. The method for selectively, directly cooling a hot aisle of a data center according to claim 14, further comprising:
operating the relief damper by an electric actuator provided outside the hot aisle.

19. The method for selectively, directly cooling a hot aisle of a data center according to claim 14, further comprising:
sensing whether a person is present in the hot aisle; and
controlling the relief damper based on whether a person is in the hot aisle.

20. The method for selectively, directly cooling a hot aisle of a data center according to claim 14, further comprising the step of indicating when the relief damper is in the open position.

21. In a data center having at least one IT rack, at least one hot aisle, at least one cooling aisle, and a source of cooling air, the improvement comprising:
a relief damper to selectively allow cooling air from the source of cooling air directly into the at least one hot aisle; and
a mechanism to control the relief damper between open and closed positions.

22. The improvement for a data center according to claim 21, wherein
the source of cooling air includes a plenum formed below panels of an access floor system and the relief damper is positioned in an opening in the panels.

23. The improvement for a data center according to claim 22, wherein the mechanism is a mechanical actuator.

24. The improvement for a data center according to claim 23, further comprising an indicator that emits a signal when the relief damper is in the open position.

25. The improvement for a data center according to claim 21, wherein the mechanism is an electric actuator.

26. The improvement for a data center according to claim 25, wherein the mechanism causes both the relief damper to move from the closed position to the open position and a data center closure to open to permit access to the at least one hot aisle.

27. The improvement for a data center according to claim 21, further comprising:
a hot aisle occupation sensor that senses whether a person is present in the at least one hot aisle;
wherein output from the hot aisle occupation sensor is used to at least partially control the position of the relief damper.

28. The improvement for a data center according to claim 27, wherein the hot aisle occupation sensor comprises a motion sensor.

29. The improvement for a data center according to claim 21, further comprising:
an actuator positioned outside the at least one hot aisle that, upon being actuated, signals the mechanism to move the relief damper from the closed position to the open position.

30. The improvement for a data center according to claim 29, further comprising:
a display unit that is positioned outside the at least one hot aisle and that indicates the temperature in the at least one hot aisle.

31. A data center comprising:
at least one IT rack;
a source of cooling air;
at least one hot aisle on one side of the at least one IT rack;
at least one cold aisle on a second side of the at least one IT rack, the cold aisle receiving cooling air from the source of cooling air;
a relief damper that selectively allows the cooling air from the source of cooling directly into the at least one hot aisle; and
a mechanism to control the relief damper between open and closed positions.

32. The data center according to claim 31, wherein
the source of cooling air includes a plenum formed below panels of an access floor system and the relief damper is positioned in an opening in the panels.

33. The data center according to claim 32, wherein the mechanism is a mechanical actuator.

34. The data center according to claim 33, further comprising an indicator that emits a signal when the relief damper is in the open position.

35. The data center according to claim 31, wherein the mechanism is an electric actuator.

36. The data center according to claim 35, wherein the mechanism causes both the relief damper to move from the closed position to the open position and a data center closure to open to permit access to the at least one hot aisle.

37. The data center according to claim 31, further comprising:
a hot aisle occupation sensor that senses whether a person is present in the at least one hot aisle;
wherein output from the hot aisle occupation sensor is used to at least partially control the position of the relief damper.

38. The data center according to claim 31, wherein the hot aisle occupation sensor comprises a motion sensor.

39. The data center according to claim 31, further comprising:
actuator positioned outside the at least hot aisle that, upon being actuated, signals the mechanism to move the relief damper from the closed position to the open position.

40. The data center according to claim 39, further comprising:
a display unit that is positioned outside the at least one hot aisle and that indicates the temperature in the at least one hot aisle.
